(19) United States
(12) Patent Application Publication
(10) Pub. No.: US 2026/0190908 A1
(43) Pub. Date: Jul. 2, 2026

(54) SUBSTRATE PROCESSING APPARATUS AND SUBSTRATE PROCESSING METHOD

(71) Applicant: SEMES CO., LTD., Cheonan-si (KR)

(72) Inventors: Yong Hoon HONG, Seoul (KR); Jin Ah HAN, Cheonan-si (KR); Boo Seok YANG, Busan (KR); Eon Jun PARK, Busan (KR); Dong Uk LEE, Seoul (KR); Hyeon Suk PARK, Cheonan-si (KR)

(73) Assignee: SEMES CO., LTD., Cheonan-si (KR)

(21) Appl. No.: 19/429,670

(22) Filed: Dec. 22, 2025

(30) Foreign Application Priority Data
Dec. 26, 2024 (KR) 10-2024-0197651

(51) Int. Cl. H10P 72/00

(52) U.S. Cl. CPC H10P 72/0422

(57) ABSTRACT

Disclosed is an apparatus of processing a substrate, the apparatus including: a liquid treating chamber for processing a substrate with a treatment liquid; a recovery tank for recovering the treatment liquid used in the liquid treating chamber through a recovery pipe; and a supply pipe for supplying the treatment liquid recovered from the recovery tank to the liquid treating chamber, in which the recovery tank includes: a tank body having a storage space in which the used treatment liquid is stored; a decompression pipe connected to the storage space and having an opening/closing valve installed; and a decompressor connected to the decompression pipe to decompress the storage space.

### CROSS-REFERENCE TO RELATED APPLICATION

This application claims priority to and the benefit of Korean Patent Application No. 10-2024-0197651 filed in the Korean Intellectual Property Office on Dec. 26, 2024, the entire contents of which are incorporated herein by reference.

### TECHNICAL FIELD

The present invention relates to a substrate processing apparatus and a substrate processing method, and more particularly, to a substrate processing apparatus and a substrate processing method that are capable of preventing a treatment liquid from flowing back when recovering the used treatment liquid.

### BACKGROUND ART

The semiconductor manufacturing process requires various chemical treatments, and for this purpose, a multi-chamber method is widely used. In this method, a plurality of process chambers is used, and each chamber independently processes a substrate using a treatment liquid. The treatment liquid used in each chamber is removed through a discharge pipe, and the discharged treatment liquid may be recovered through a recovery pipe and reused after a certain treatment process.

However, in such a multi-chamber system, problems may occur when the treatment liquid is discharged from the plurality of chambers at the same time. When the treatment liquid is discharged from the plurality of process chambers at the same time, interference between the treatment liquid may occur in the discharge pipe and the recovery pipe, resulting in a stagnation phenomenon.

In addition, in order to reuse the recovered treatment liquid, particles in the treatment liquid must be removed and the ion concentration must be adjusted. However, if a filter is installed in the recovery pipe to remove particles and the liquid supply unit is installed to adjust the ion concentration, a stagnation phenomenon in the recovery pipe may occur.

This stagnation phenomenon hinders the smooth discharge of the treatment liquid and in serious cases, may cause a problem that the treatment liquid flows back into the process chamber. Backflow of the treatment liquid may lead to contamination of the process chamber, which may consequently seriously affect the quality and efficiency of the semiconductor manufacturing process.

### SUMMARY OF THE INVENTION

The present invention has also been made in an effort to provide a substrate processing apparatus and a substrate processing method capable of preventing a back flow of a treatment liquid to a process chamber when the treatment liquid is recovered.

The present invention has also been made in an effort to provide a substrate processing apparatus and substrate processing method capable of adjusting a concentration of dissolved oxygen in a recovered treatment liquid.

The present invention has been made in an effort to provide a substrate processing apparatus and a substrate processing method capable of efficiently removing particles from a recovered treatment liquid.

The present invention has been made in an effort to provide a substrate processing apparatus and a substrate processing method capable of adjusting a concentration of ions in a recovered treatment liquid.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a liquid treating chamber for processing a substrate with a treatment liquid; a recovery tank for recovering the treatment liquid used in the liquid treating chamber through a recovery pipe; and a supply pipe for supplying the treatment liquid recovered from the recovery tank to the liquid treating chamber, wherein the recovery tank may include, a tank body having a storage space in which the used treatment liquid is stored; a decompression pipe connected to the storage space and having an opening/closing valve installed; and a decompressor connected to the decompression pipe to decompress the storage space.

Further, an exemplary embodiment of the present disclosure, a method of processing a substrate, the method comprising: processing a substrate by supplying a treatment liquid from a liquid treating chamber, and directly recovering the used treatment liquid into a recovery tank through a recovery pipe, wherein an inside of the recovery tank may be decompressed while the treatment liquid is recovered to the recovery tank.

Further, an exemplary embodiment of the present disclosure, an apparatus for processing a substrate, the apparatus comprising: a liquid treating chamber for processing a substrate with a treatment liquid; a recovery tank for recovering the treatment liquid used in the liquid treating chamber through a recovery pipe; and a first supply pipe for supplying the treatment liquid recovered from the recovery tank to a supply tank; a second supply pipe for supplying the treatment liquid stored in the supply tank to the liquid treating chamber; a first filter installed in the recovery pipe; a chemical liquid supply pipe connected to the recovery pipe and supplying a chemical liquid to the recovery pipe; and a chemical liquid supply source connected to the chemical liquid supply pipe, wherein the recovery tank may include, a tank body having a storage space in which the used treatment liquid is stored; a decompression pipe connected to the storage space and having a first opening/closing valve installed; a decompressor connected to the decompression pipe to decompress the storage space; a circulation pipe for circulating the liquid in the tank body; a second filter installed in the circulation pipe; a nozzle provided to be immersed in the treatment liquid stored in the storage space; a gas supply pipe connected to the nozzle; a gas supply source connected to the gas supply pipe; a second opening/closing valve installed in the gas supply pipe; and a dissolved oxygen measuring device for measuring dissolved oxygen of the treatment liquid stored in the storage space.

According to the exemplary embodiment of the present invention, it is possible to prevent a back flow of a treatment liquid to a process chamber when the treatment liquid is recovered.

Further, according to the exemplary embodiment of the present invention, it is possible to adjust a concentration of dissolved oxygen in a recovered treatment liquid.

Further, according to the exemplary embodiment of the present invention, it is possible to efficiently remove particles from a recovered treatment liquid.

Further, according to the exemplary embodiment of the present invention, it is possible to adjust a concentration of ions in a recovered treatment liquid.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a top plan view schematically illustrating a substrate processing apparatus according to an exemplary embodiment of the present invention.

FIG. 2 is a diagram schematically illustrating an exemplary embodiment of a liquid treating chamber of FIG. 1.

FIG. 3 is a diagram illustrating a treatment liquid supply unit according to the exemplary embodiment of the present invention.

FIG. 4 is a diagram illustrating an exemplary embodiment of a recovery tank of FIG. 3.

FIG. 5 is a diagram schematically illustrating a state in which a plurality of liquid treating chambers is connected to recovery pipes.

FIG. 6 is a diagram schematically illustrating another exemplary embodiment of the liquid treating chamber of FIG. 1.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as an object to be treated. However, the technical idea of the present invention may be applied to devices used for treating other types of substrates other than wafers as objects to be treated.

Hereinafter, a substrate processing apparatus and a substrate processing method according to the present invention will be described with reference to the accompanying drawings. The description of the substrate processing apparatus deals with the structure and function of each component of the substrate processing apparatus, and the description of the substrate processing method deals with a method of controlling these components. The description of each component includes structural characteristics and operation methods, and thus the operating principle of the substrate processing apparatus may be clearly understood.

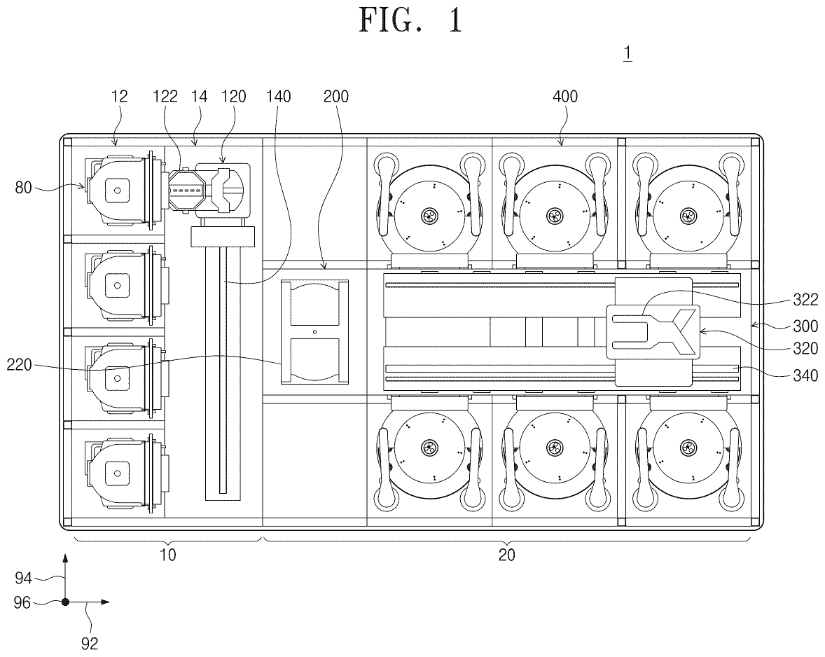

FIG. 1 is a top plan view schematically illustrating a substrate processing apparatus according to an exemplary embodiment of the present invention. Referring to FIG. 1, a substrate processing apparatus includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96. The controller 30 is provided to control all operable components of the substrate processing apparatus. Accordingly, the controller 30 enables efficient operation and management of the substrate processing apparatus.

The controller 30 may effectively manage and execute the entire substrate processing process, such as movement of the substrate W, position adjustment, and processing process execution, by precisely controlling each component of the index module 10 and the processing module 20. The controller 30 adjusts the operation of each component according to the stored processing recipe, and selectively analyzes information received from the sensor to optimize the processing process in real time. Accordingly, the controller 30 enables substrate processing with high precision and consistency.

The controller 30 includes a process controller, a user interface, and a storage unit. The process controller is composed of a microprocessor (computer) and executes overall control of the substrate processing apparatus. In this process, the process controller receives data from various sensors in the apparatus, monitors and controls the processing situation in real time. The process controller is electrically connected to the sensor, and may receive information by wire or wirelessly. The storage unit stores a control program and a processing recipe. The control program manages processing executed in the substrate processing apparatus under the control of the process controller. The processing recipe is a program for executing processing to each component according to various data and processing conditions. The user interface and the storage unit are connected to the process controller. The processing recipe is stored in a storage medium in the storage unit, which may be a portable disk such as a hard disk, a CD-ROM, a DVD, or a semiconductor memory such as a flash memory. The user interface and the storage unit are connected to the process controller.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal direction is the second direction 94 is provided within the index frame 14, and the index robot 120 may be provided to be movable on the guide rail 140. The index robot 120 includes a hand 122 on which the substrate W is placed, and the hand 122 may be provided to be movable forward and backward, rotatable about the third direction 96, and movable along the third direction 96. A plurality of hands 122 are provided to be spaced apart in the vertical direction, and the hands 122 may move forward and backward independently of each other.

The treating module 20 includes a buffer chamber 200, a transfer chamber 300, and a process chamber 400.

The buffer chamber 200 provides a space in which the substrate W loaded into the treating module 20 and the substrate W unloaded from the treating module 20 stay temporarily. The buffer chamber 200 includes a plurality of buffers 220 on which the substrate W is temporarily placed. The buffers 220 may be disposed while being spaced apart from each other in the third direction 96. A front face and a rear face of the buffer chamber 200 are opened. The front face is a face facing the index module 10, and the rear face is a face facing the transfer chamber 300. The index robot 120 may approach the buffer chamber 200 through the front face, and the transfer robot 320 may approach the buffer chamber 200 through the rear face.

The transfer chamber 300 transfers the substrate W between the buffer chamber 200 and the liquid treating chamber 400. The transfer chamber 300 may be provided so that a longitudinal direction is the first direction 92. The buffer chamber 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 94. The buffer chamber 200 may be located at one end of the transfer chamber 300. The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. The plurality of hands 322 is provided while being spaced apart from each other in the vertical direction, and is capable of independently moving forward and backward.

The process chamber 400 performs a process of processing the substrate W loaded into the process chamber 400. According to an example, the process chamber 400 performs a process of liquid-treating the substrate W by supplying a treatment liquid onto the substrate W. The treatment liquid may be various types of liquids used in a wet etching process or a cleaning process for removing a film on the surface of the substrate W. The treatment liquid may be at least one selected from hydrofluoric acid (HF), sulfuric acid (H₃SO₄), hydrogen peroxide (H₂O₂), a mixture solution containing hydrogen peroxide (H₂O₂), nitric acid (HNO₃), phosphoric acid (H₃PO₄), ozone water, SC-1 solution (a mixture solution of ammonium hydroxide (NH₄OH), hydrogen peroxide (H₂O₂), and water (H₂O)), and the like. According to an example, the treatment liquid may be an etching liquid for etching titanium nitride (TiN). However, the present invention is not limited thereto, and the treatment liquid may be various other types of treatment liquids which may be used in the substrate processing process. Hereinafter, the present invention will be described based on the case where the process chamber 400 is a liquid treating chamber for treating the substrate W with at least one of the foregoing treatment liquids as an example.

A plurality of liquid treating chambers 400 is provided. The liquid treating chambers 400 are respectively disposed on opposite sides of the transfer chamber 300. At each of opposite sides of the transfer chamber 300, the liquid treating chambers 400 may be provided in an array of A×B (each of A and B is 1 or a natural number greater than 1) in the first direction 92 and the third direction 96.

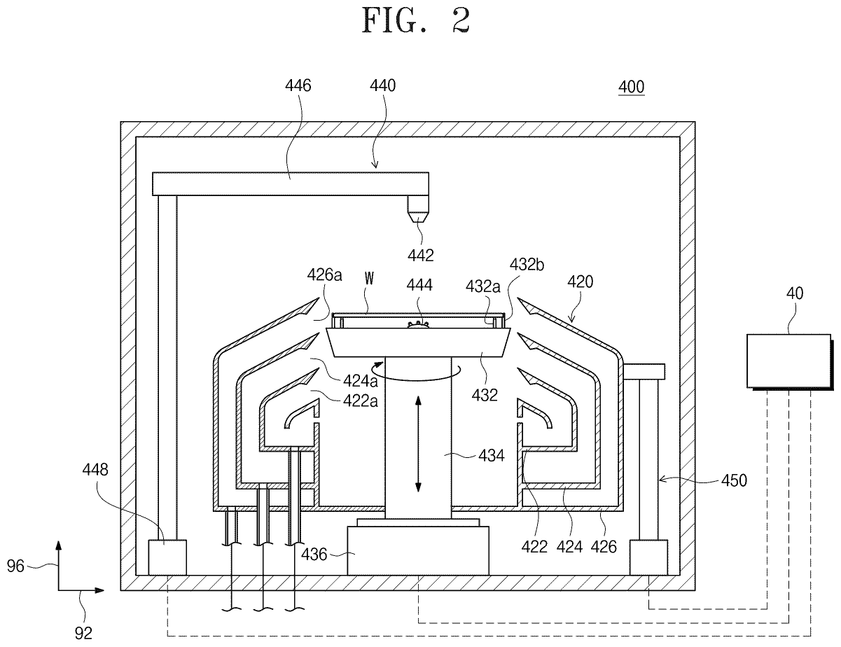

FIG. 2 is a diagram schematically illustrating an exemplary embodiment of the liquid treating chamber 400 of FIG. 1. Referring to FIG. 2, the liquid treating chamber 400 includes a housing 410, a cup body 420, a support unit 440, a nozzle unit 460, a lifting unit 450, and a controller.

The housing 410 is provided in a generally rectangular parallelepiped shape. The cup body 420, the support unit 430, and the nozzle unit 440 are disposed within the housing 410.

The cup body 420 has a processing space with an open top, and the substrate W is liquid-processed in the processing space. The support unit 430 supports the substrate W in the treatment space. The nozzle unit 440 supplies a liquid onto the substrate W supported on the support unit 430. The liquid may be provided in a plurality of types, and may be sequentially supplied onto the substrate W. The lifting unit 450 adjusts a relative height between the cup body 420 and the support unit 430.

According to an example, the cup body 420 includes a plurality of recovery containers 422, 424, and 426. Each of the recovery containers 422, 424, and 426 has a recovery space of recovering the liquid used for the processing of the substrate. Each of the recovery containers 422, 424, and 426 is provided in a ring shape surrounding the support unit 430. As the liquid treating process proceeds, the treatment liquid scattered by the rotation of the substrate W is introduced into the recovery space through the inlets 422a, 424a, and 426a of the respective recovery containers 422, 424, and 426. According to the example, the cup body 420 includes a first recovery container 422, a second recovery container 424, and a third recovery container 426. The first recovery container 422 is disposed to surround the support unit 430, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 430 includes a support plate 432 and a drive shaft 434. An upper surface of the support plate 432 may be provided in a generally circular shape, and may have a diameter larger than a diameter of the substrate W. Further, a support pin 432a supporting the rear surface of the substrate W is provided at the center of the support plate 432, and the upper end of the support pin 432a is provided to protrude from the support plate 432 so that the substrate W is spaced apart from the support plate 432 by a predetermined distance. A chuck pin 432b is provided at an edge of the support plate 432. The chuck pin 432b is provided to protrude upward from the support plate 432, and supports the side portion of the substrate W so that the substrate W does not deviate from the support unit 430 when the substrate W is rotated. The drive shaft 434 is driven by the driver 436, is connected to the center of the bottom surface of the substrate W, and rotates the support plate 432 about its central axis.

The nozzle unit 440 includes a first nozzle 442 and a second nozzle 444. The first nozzle 442 supplies the treatment liquid onto the substrate W. The second nozzle 444 supplies a treatment liquid different from the treatment liquid supplied by the first nozzle 442 onto the substrate W.

The first nozzle 442 and the second nozzle 444 are supported by different arms 441, respectively, and these arms 441 may be moved independently. Optionally, the first nozzle 442 and the second nozzle 444 may be mounted on the same arm and moved at the same time.

Optionally, the nozzle unit 440 may further include one or a plurality of nozzles in addition to the first nozzle 442 and the second nozzle 444. The added nozzle may supply another type of treatment liquid to the substrate. For example, another type of treatment liquid may be an acid solution or a base solution for removing foreign substances on the substrate. In addition, another type of treatment liquid may be alcohol having surface tension lower than water. For example, the alcohol may be isopropyl alcohol.

The lifting unit 450 moves the cup body 420 in the up and down direction. By the up and down movement of the cup body 420, a relative height between the cup body 420 and the substrate W is changed. Accordingly, the recovery containers 422, 424, and 426 for recovering the treatment liquid are changed according to the type of liquid supplied to the substrate W, and thus the liquids may be separated and recovered. Unlike the description, the cup body 420 is fixedly installed, and the lifting unit 450 may move the support unit 430 in the vertical direction.

In addition, the treating module 20 may further include a treatment liquid supply unit 40 to supply a treatment liquid to the liquid treating chamber 400. The treatment liquid supply unit 40 may include a portion for processing the substrate W by supplying the treatment liquid and a portion for recovering and recycling the used treatment liquid. According to an example, a supply tank for storing a treatment liquid to be supplied and a recovery tank for recovering a used treatment liquid are provided, and the substrate W may be processed by supplying the treatment liquid from the recovery tank to the supply tank again. In addition to the supply tank and the recovery tank, the treatment liquid supply unit 40 may include various configurations required to supply the treatment liquid to the liquid treating chamber 400. According to an example, the treatment liquid supply unit 40 may include a recovery tank 500, a recovery pipe 501, a chemical replenishment unit 502, a filter 503, and a supply tank.

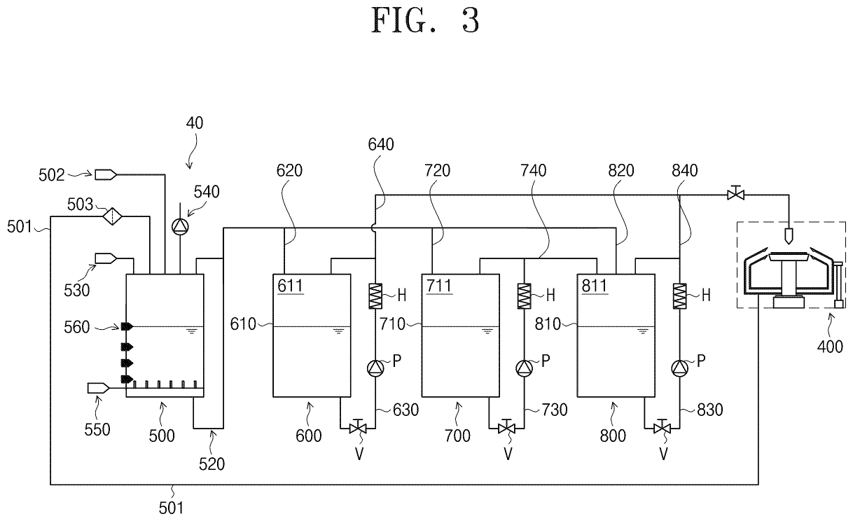

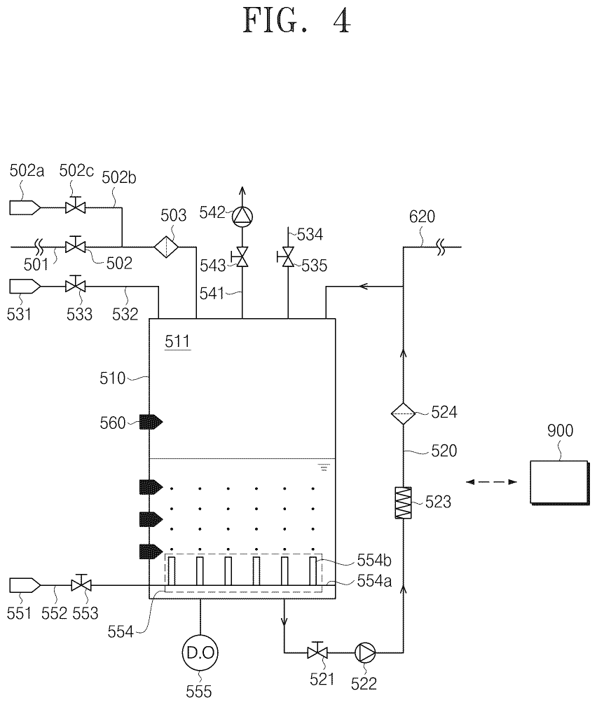

FIG. 3 is a diagram illustrating the supply tank and the recovery tank connected to the supply tank according to the exemplary embodiment of the present invention, and FIG. 4 is a diagram illustrating an exemplary embodiment of the recovery tank of FIG. 3. Referring to FIGS. 3 and 4, the recovery tank 500 is connected to the liquid treating chamber 400 through the recovery pipe 501. The liquid treating chamber 400 and the recovery tank 500 are directly connected through the recovery pipe 501. The treatment liquid used in the liquid treating chamber 400 is recovered in the recovery tank 500 through the recovery pipe 501. A chemical liquid replenishment unit 502 and the first filter 503 may be installed in the recovery pipe 501.

The chemical liquid replenishment unit 502 is provided to replenish the chemical liquid with the recovery tank 500. The chemical liquid replenishment unit 502 may include a chemical liquid supply source 502a, a chemical liquid supply pipe 502b, and an opening/closing valve 502c. The chemical liquid supply source 502a stores a chemical liquid to be replenished in the recovery tank 500. According to an example, the chemical liquid may be a treatment liquid. However, the present invention is not limited thereto, and when the treatment liquid is a mixed liquid in which a plurality of chemical liquids is mixed, the chemical liquid may be any one of a plurality of chemical liquids. The chemical liquid supply pipe 502b provides a path through which the chemical liquid is supplied from the chemical liquid supply source 502a. The chemical liquid supply pipe 502b is connected to the chemical liquid supply source 502a and is connected to the recovery pipe 501.

The opening/closing valve 502c opens and closes the chemical liquid supply pipe 502b. The controller 30 may control whether to replenish the chemical liquid by controlling the opening/closing valve 502c. The controller 30 may replenish the chemical liquid by opening the opening/closing valve 502c. According to an example, the controller 30 may replenish the chemical liquid to adjust a concentration of the recovered treatment liquid. Further, when a water level of the treatment liquid in the tank body 510 to be described later is low, the controller 30 may replenish the chemical liquid to match the water level. The controller 30 may control the opening/closing valve 502c to supply the chemical liquid to the recovery pipe 501 while the treatment liquid is recovered to the recovery tank 500. The chemical liquid supply source 502a and the chemical liquid supply pipe 502b may be provided with a supply means, which is not illustrated, which is required to supply the chemical liquid.

The first filter 503 primarily filters the recovered treatment liquid. The first filter 503 may remove particles from the recovered treatment liquid. Accordingly, it is possible to efficiently shorten the time filtered by a second filter 524 to be described later. In addition, the first filter 503 may be installed downstream from the chemical liquid replenishment unit 502. Accordingly, the chemical liquid supplied from the chemical liquid replenishment unit 502 may also be filtered.

The recovery tank 500 may include a tank body 510, a circulation pipe 520, a purge unit 530, a decompression unit 540, a gas supply unit 550, and a level sensor 560.

The tank body 510 provides a storage space 511 therein. The recovered treatment liquid is stored in the storage space 511. The circulation pipe 520, the purge unit 530, the decompression unit 540, the gas supply unit 550, and a level sensor 560 may be installed in the tank body 510.

The treatment liquid stored in the storage space 511 may be circulated through the circulation pipe 520. The circulation pipe 520 may be provided so that a treatment liquid circulates to the outside of the tank body 510. According to an example, the circulation pipe 520 may be provided such that a treatment liquid flows out from a lower surface of the tank body 510 and is introduced into an upper surface of the tank body 510. A valve 521, a pump 522, a heater 523, a second filter 524, and a first supply pipe 640 may be installed in the circulation pipe 520. The valve 521 opens and closes the circulation pipe 520. The pump 522 provides flow force so that a treatment liquid flows through the circulation pipe 520. The heater 523 may heat the treatment liquid. The filter 524 filters the treatment liquid.

The controller 30 may open the valve 521 to control the treatment liquid to flow through the circulation pipe 520. The treatment liquid stored in the storage space 511 may be circulated a plurality of times through the circulation pipe 520. The treatment liquid flowing through the circulation pipe 520 may be heated by the heater 523 and filtered by the filter 524. Accordingly, the temperature of the treatment liquid stored in the storage space 511 rises, and particles in the treatment liquid may be removed. The controller 30 may control the recovered treatment liquid to circulate until the recovered treatment liquid reaches a preset temperature and impurities, such as particles, in the treatment liquid become less than or equal to a preset concentration.

The purge unit 530 may purge the storage space 511. The purge unit 530 may include a purge gas supply source 531, a purge gas supply pipe 532, an opening/closing valve 533, an exhaust pipe 534, and an opening/closing valve 535.

The purge gas supply source 531 stores purge gas. According to an example, the purge gas may be nitrogen gas. The purge gas is supplied to the storage space 511 through the purge gas supply pipe 532. The opening/closing valve 533 is provided to open and close the purge gas supply pipe 532. The supplied purge gas is exhausted along the exhaust pipe 534. The exhaust pipe 534 may be connected to external atmosphere or an external gas exhaust facility. The purge gas may be naturally exhausted along the exhaust pipe 534. The opening/closing valve 535 is provided to open and close the exhaust pipe 534.

The controller 30 may open the opening/closing valve 533 and the opening/closing valve 535 to perform a purge operation. Furthermore, the controller 30 may close the opening/closing valve 535 during a decompression operation which will be described later.

The decompression unit 540 controls the storage space 511 to be decompressed. The decompression unit 540 may include a decompression pipe 541, a decompressor 542, and an opening/closing valve 543. The decompression pipe 541 is connected to the storage space 511. The decompressor 542 decompresses the storage space 511 through the decompression pipe 541. Accordingly, negative pressure is formed in the storage space 511. The negative pressure may promote recovery of a treatment liquid from the recovery pipe 501 connected to the storage space 511. According to an example, the decompressor 542 may be a pump. The opening/closing valve 543 is provided to open and close the decompression pipe 541.

The controller 30 may open the opening/closing valve 543 and operate the decompressor 542 to perform the decompression operation. According to an example, the controller 30 may control the decompressor 542 and the opening/closing valve 543 to decompress the storage space 511 while the used treatment liquid is recovered through the recovery pipe 501. Further, the controller 30 may control the decompressor 542 to decompress the storage space 511 only when the opening/closing valve 543 is opened. During the decompression operation, the controller 30 closes the exhaust pipe 534 to prevent the decompression efficiency of the decompressor 542 from being lowered.

The gas supply unit 550 supplies gas to the treatment liquid stored in the storage space 511. The gas supply unit 550 may include a gas supply source 551, a gas supply pipe 552, an opening/closing valve 553, a gas nozzle 554, and a dissolved oxygen measuring device 555. The gas supply source 551 stores gas supplied to the gas nozzle 554. According to an example, the gas may be nitrogen gas. The gas supply source 551 is connected to one side of the gas supply pipe 552, and the gas nozzle 554 is connected to the other side of the gas supply pipe 552. The gas is supplied to the gas nozzle 554 through the gas supply pipe 552. The gas nozzle 554 discharges the supplied gas. The gas nozzle 554 is provided at the lower side of the storage space 511. Accordingly, the gas nozzle 554 may be provided to be immersed in the treatment liquid stored in the storage space 551 and discharge gas in the treatment liquid. The gas nozzle 554 is provided to have a longitudinal direction. According to an example, the gas nozzle 554 may have a body 554a and a discharge portion 554b. The body 554a is provided in a shape having a longitudinal direction. One side of the body 554a may be connected to the gas supply pipe 552. The discharge portion 554b is provided on the surface of the body 554a. The discharge portion 554b discharges the gas supplied to the body 554a. A plurality of discharge portions 554b may be provided. A plurality of discharge portions 554b may be arranged along the longitudinal direction of the body 554a. However, the present invention is not limited thereto, and the discharge portion 554b may be provided in the form of an opening formed in the surface of the body 554a. The gas discharged from the gas nozzle 554 may reduce the partial pressure of oxygen in the treatment liquid, and may reduce dissolved oxygen in the treatment liquid while forming bubbles.

The dissolved oxygen measuring device 555 is provided to measure dissolved oxygen in the treatment liquid stored in the storage space 511. The dissolved oxygen measuring device 555 is connected to the controller 30 through wired or wireless communication to transmit data.

The controller 30 may control whether or not to discharge gas from the gas nozzle 554 based on the dissolved oxygen measured by the dissolved oxygen measuring device 555. When the dissolved oxygen value measured by the dissolved oxygen measuring device is equal to or greater than a preset value, the controller 30 opens the opening/closing valve 553 to supply gas to the gas nozzle 554. The gas nozzle 554 may discharge the supplied gas to form bubbles in the treatment liquid to lower dissolved oxygen in the treatment liquid. The controller 30 may receive feedback from the dissolved oxygen measuring device 555 and control the gas supply unit 550 so that the dissolved oxygen value is less than the preset value.

n the above example, the present invention has been described based on the case where the gas supply unit 550 includes the gas nozzle 554 as an example. However, the present invention is not limited thereto, and a bubbler may be provided instead of the gas nozzle 554.

The level sensor 560 is provided to measure a water level of the treatment liquid in the tank body 510. The level sensor 560 may measure the water level of the treatment liquid by dividing the level of the treatment liquid into several stages. According to an example, the water level of the treatment liquid may be measured by subdividing the level into four stages. The water levels of the four stages may be divided into an H level (high operating level), an MR level (middle refill operating level), an M level (middle operating level), and an L level (low operating level).

The controller 30 may control whether the chemical liquid is replenished by the chemical liquid replenishment unit 570 based on the water level measured by the level sensor 560, whether the treatment liquid is circulated in the circulation pipe 520, and whether the treatment liquid is supplied from the recovery tank 500 to the supply tank to be described later.

The supply tank may include a plurality of tanks. Hereinafter, the present invention will be described based on the case where the supply tank includes a first tank 600, a second tank 700, and a third tank 800 as an example.

The first tank 600 may receive a treatment liquid from the recovery tank 500. The first tank may include a first tank body 610, a first inflow pipe 620, a first circulation pipe 630, and a first supply pipe 640. The first tank body 610 provides a first storage space 611 for storing a treatment liquid therein. The first inflow pipe 620 connects the recovery tank 500 and the first tank 600. Accordingly, the treatment liquid recovered from the recovery tank 500 to the first tank 600 may be supplied. The first circulation pipe 630 circulates the treatment liquid. The first circulation pipe 630 may be provided so that the treatment liquid circulates to the outside of the first tank body 610. According to an example, the first circulation pipe 630 may be provided so that a treatment liquid flows out from a lower surface of the first tank body 610 and is introduced into an upper surface of the first tank body 610. The first supply pipe 640 may be installed in the first circulation pipe 630. The first supply pipe 640 may be connected to the liquid treating chamber 400. Accordingly, the treatment liquid may be supplied from the first tank 600 to the liquid treating chamber 400. The first inflow pipe 620, the first circulation pipe 630, and the first supply pipe 640 may be provided with necessary components, such as a pump P, a heater H, and a valve V, required for controlling the flow of the treatment liquid.

The second tank 700 may receive a treatment liquid from the recovery tank 500. The second tank may include a second tank body 710, a second inflow pipe 720, a second circulation pipe 730, and a second supply pipe 740. The second tank body 710 provides a second storage space 711 for storing a treatment liquid therein. The second inflow pipe 720 connects the recovery tank 500 and the second tank 700. Accordingly, the treatment liquid recovered from the recovery tank 500 to the second tank 700 may be supplied. The second circulation pipe 730 circulates the treatment liquid. The second circulation pipe 730 may be provided to circulate a treatment liquid to the outside of the second tank body 710. According to an example, the circulation pipe 730 may be provided so that a treatment liquid flows out of a lower surface of the second tank body 710 and is introduced into an upper surface of the second tank body 710. The second supply pipe 740 may be installed in the second circulation pipe 730. The second supply pipe 740 may be connected to the third tank 800. Accordingly, the treatment liquid may be supplied from the second tank 700 to the third tank 800. The second inflow pipe 720, the second circulation pipe 730, and the second supply pipe 740 may be provided with necessary components, such as a pump P, a heater H, and a valve V, required for controlling the flow of the treatment liquid.

The third tank 800 may receive a treatment liquid from the recovery tank 500. The third tank may include a third tank body 810, a third inflow pipe 820, a third circulation pipe 830, and a third supply pipe 840. The third tank body 810 provides a third storage space 811 for storing a treatment liquid therein. The third inflow pipe 820 connects the recovery tank 500 and the third tank 800. Accordingly, the treatment liquid recovered from the recovery tank 500 to the third tank 800 may be supplied. The third circulation pipe 830 circulates the treatment liquid. The third circulation pipe 830 may be provided to circulate the treatment liquid to the outside of the third tank body 810. According to an example, the circulation pipe 830 may be provided such that the treatment liquid flows out of a lower surface of the third tank body 810 and is introduced into the upper surface of the third tank body 810. The third supply pipe 840 may be installed in the third circulation pipe 830. The third supply pipe 840 may be connected to the liquid treating chamber 400. Accordingly, the treatment liquid may be supplied from the third tank 800 to the liquid treating chamber 400. The third inflow pipe 820, the third circulation pipe 830, and the third supply pipe 840 may be provided with necessary components, such as a pump P, a heater H, and a valve V, required for controlling the flow of the treatment liquid.

The controller 30 may control the recovered treatment liquid to be supplied from the recovery tank 500 to any one of the first tank 600, the second tank 700, and the third tank 800. According to an example, the controller 30 may control the recovered treatment liquid to be supplied to the first tank 600 when the second tank 700 and the third tank 800 are not available, and the recovered treatment liquid to be supplied to the second tank 700 when additional temperature adjustment is required.

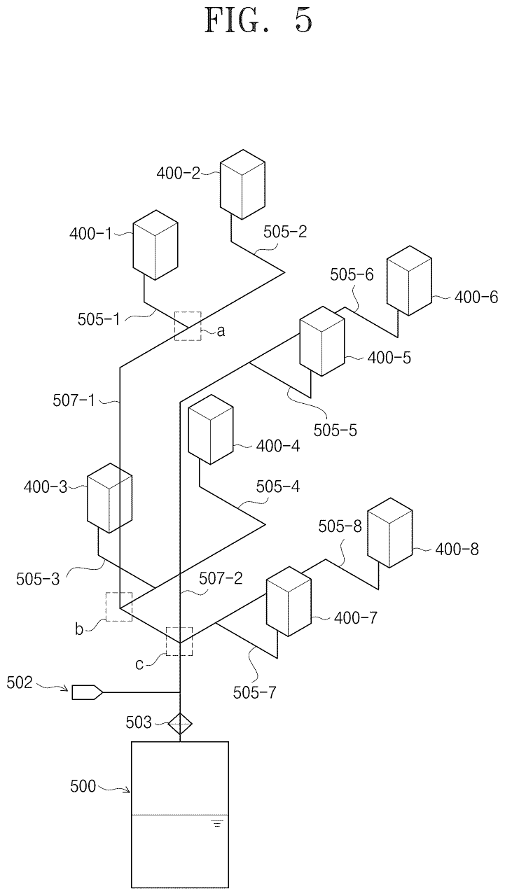

FIG. 5 is a diagram schematically illustrating a state in which the plurality of liquid treating chambers is connected to the recovery pipes. Referring to FIG. 5, the plurality of liquid treating chambers 400 may be provided in an array of A×B (A and B are each 1 or a natural number larger than 1) in the first direction 92 and the third direction 96. The recovery pipe 501 may include a discharge pipe 505 and a collective pipe 507.

The discharge pipe 505 is connected to the liquid treating chamber 400. The discharge pipes 505 are provided in plural (505-1 to 505-8) and may be individually connected to the liquid treating chambers 400-1 to 400-8, respectively. The treatment liquid used in the liquid treating chamber 400 is discharged to the outside of the liquid treating chamber 400 through the discharge pipe 505. The plurality of discharge pipes 505-1 to 505-8 is connected to the collective pipes 507.

The collective pipes 507 are provided to be connected with the plurality of discharge pipes 505-1 to 505-8. The collective pipe 507 guides the treatment liquid discharged from the discharge pipe 505 to the recovery tank 500. A plurality of collective pipes 507 may be provided. According to an example, the collective pipe 507 may include a collective pipe 507-1 and a collective pipe 507-2. The collective pipe 507-1 is provided to be connected to the discharge pipes 505-1 to 505-4 coupled to the liquid treating chambers 400-1 to 400-4 located on one side of the transfer chamber 300, and the collective pipe 507-2 is provided to be connected to the discharge pipes 505-5 to 505-8 coupled to the liquid treating chambers 400-5 to 400-8 located on the other side of the transfer chamber 300. In addition, one of the collective pipes 507-1 and 507-2 may be provided to be connected to the other. According to an example, the chemical liquid replenishment unit 502 and the first filter 503 described above may be installed on the downstream side of the collective pipe 507.

When the treatment liquid is discharged from at least some of the plurality of liquid treating chambers 400-1 to 400-8 at the same time, interference between the treatment liquids may occur in the discharge pipes 505-1 to 505-8 and the collective pipes 507-1 and 507-2. For example, a stagnation phenomenon recovered treatment liquid may occur at a first point a at which the discharge pipe 505 is connected to the collective pipe 507, a second point b at which the vertical pipe and the horizontal pipe are connected among the collective pipes 507, and a third point c at which any one collective pipe 507-1 is connected to the other collective pipe 507-2. This stagnation phenomenon may vary in degree depending on the amount of the treatment liquid, the flow rate of the treatment liquid, and the like. In the exemplary embodiment as illustrated in FIG. 5, since the amount of the treatment liquid supplied to the third point c is the largest, the stagnation phenomenon at the third point c among the first to third points a, b, and c is the most severe. According to the same principle, the stagnation phenomenon may be severe in the order of the second point b and the first point a after the third point c.

This stagnation phenomenon may be minimized by the decompression unit 540 installed in the recovery tank 500. The decompression unit 540 exhausts the storage space 511 to form a negative pressure in the storage space 511. The negative pressure formed in the storage space 511 promotes the recovery of the treatment liquid flowing through the collective pipe 507 into the recovery tank 500. For example, the negative pressure formed in the storage space 511 may cause the treatment liquid stagnated at the third point c to flow into the storage space 511. When the stagnation phenomenon of the treatment liquid is resolved at the third point c, the stagnation phenomenon at the second point b and the first point a at the upstream side that have been affected by the stagnation phenomenon of the third point c may also be minimized. Resolving the stagnation phenomenon may prevent the treatment liquid discharged from the liquid treating chamber 400 from flowing back to the liquid treating chamber 400 to contaminate the liquid treating chamber 400. Accordingly, it is possible to prevent a process failure and a decrease in treatment efficiency due to contamination of the liquid treating chamber 400.

In the above-described example, the present invention has been described based on the case where the plurality of liquid treating chambers 400 is provided and a stagnation phenomenon occurs by simultaneously discharging a treatment liquid the a plurality of liquid treating chambers 400 as an example. However, the present invention is not limited thereto, and even if the treatment liquid is discharged only from any one of the liquid treating chambers 400, the stagnation phenomenon of the treatment liquid may occur depending on the shape of the recovery pipe 501.

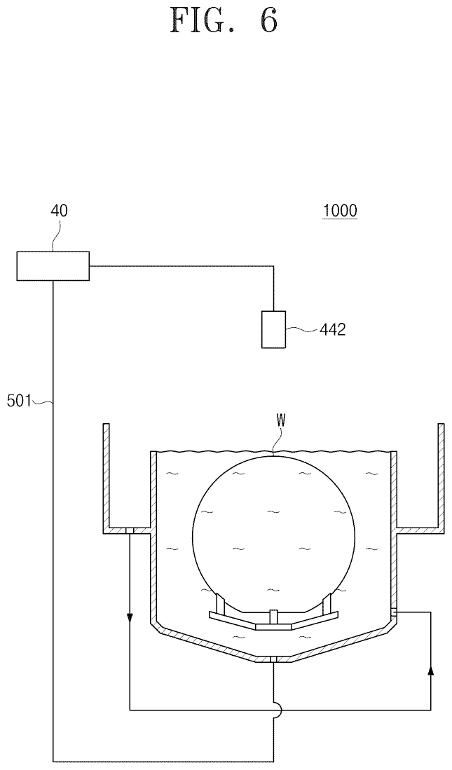

In addition, in the aforementioned example, the liquid treating chamber 400 is described as a single wafer type that liquid-treats a single substrate W, but as illustrated in FIG. 6, the liquid treating chamber 100 may be provided as a batch liquid treating chamber 1000 that may liquid-treat the plurality of substrates Ws at the same time.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. An apparatus for processing a substrate, the apparatus comprising:
a liquid treating chamber for processing a substrate with a treatment liquid;
a recovery tank for recovering the treatment liquid used in the liquid treating chamber through a recovery pipe; and
a supply pipe for supplying the treatment liquid recovered from the recovery tank to the liquid treating chamber,
wherein the recovery tank includes:
a tank body having a storage space in which the used treatment liquid is stored;
a decompression pipe connected to the storage space and having an opening/closing valve installed; and
a decompressor connected to the decompression pipe to decompress the storage space.

2. The apparatus of claim 1, wherein the liquid treating chamber and the recovery tank are directly connected through the recovery pipe.

3. The apparatus of claim 2, further comprising:
a controller,
wherein the controller controls the opening/closing valve and the decompressor to decompress the storage space while the used treatment liquid is recovered through the recovery pipe.

4. The apparatus of claim 3, wherein the controller controls the opening/closing valve and the decompressor to decompress the storage space only when the opening/closing valve is opened.

5. The apparatus of claim 1, wherein a first filter is installed in the recovery pipe.

6. The apparatus of claim 1, wherein a chemical liquid supply pipe that supplies a chemical liquid is connected to the recovery pipe, and
a chemical liquid supply source is connected to the chemical liquid supply pipe.

7. The apparatus of claim 6, wherein a first filter is installed in the recovery pipe, and
the chemical liquid supply pipe is connected upstream of the recovery pipe relative to the first filter.

8. The apparatus of claim 5, further comprising:
a circulation pipe for circulating the liquid in the tank body,
wherein a pump and a second filter are installed in the circulation pipe.

9. The apparatus of claim 1, further comprising:
a gas supply pipe for supplying gas to the treatment liquid stored in the storage space; and
a gas supply source connected to the gas supply pipe.

10. The apparatus of claim 9, wherein a nozzle is provided to be immersed in the treatment liquid stored in the storage space,
the gas supply pipe is connected to the nozzle,
the nozzle is provided to have a longitudinal direction,
a plurality of discharge holes through which gas is discharged is provided along the longitudinal direction of the nozzle, and
an opening/closing valve is installed in the gas supply pipe.

11. The apparatus of claim 10, wherein the recovery tank further includes a dissolved oxygen measuring device that measures dissolved oxygen of the treatment liquid stored in the storage space,
the apparatus further comprises a controller, and
the controller controls the opening/closing valve to decrease the dissolved oxygen in the treatment liquid stored in the storage space when a value measured by the dissolved oxygen measuring device is equal to or greater than a preset value.

12. The apparatus of claim 1, wherein the liquid treating chamber is provided in plural, and
the recovery pipe includes:
a plurality of discharge pipes connected to the plurality of liquid treating chambers, respectively; and
a collective pipe to which the plurality of discharge pipes are connected and the recovery tank is connected.

13. The apparatus of claim 2, further comprising:
a supply tank for storing the treatment liquid supplied from the recovery tank, wherein the supply pipe is connected to the supply tank and the liquid treating chamber.

14. -17. (canceled)

18. An apparatus for processing a substrate, the apparatus comprising:
a liquid treating chamber for processing a substrate with a treatment liquid;
a recovery tank for recovering the treatment liquid used in the liquid treating chamber through a recovery pipe; and
a first supply pipe for supplying the treatment liquid recovered from the recovery tank to a supply tank;
a second supply pipe for supplying the treatment liquid stored in the supply tank to the liquid treating chamber;
a first filter installed in the recovery pipe;
a chemical liquid supply pipe connected to the recovery pipe and supplying a chemical liquid to the recovery pipe; and
a chemical liquid supply source connected to the chemical liquid supply pipe,
wherein the recovery tank includes:
a tank body having a storage space in which the used treatment liquid is stored;
a decompression pipe connected to the storage space and having a first opening/closing valve installed;
a decompressor connected to the decompression pipe to decompress the storage space;
a circulation pipe for circulating the liquid in the tank body;
a second filter installed in the circulation pipe;
a nozzle provided to be immersed in the treatment liquid stored in the storage space;
a gas supply pipe connected to the nozzle;
a gas supply source connected to the gas supply pipe;
a second opening/closing valve installed in the gas supply pipe; and
a dissolved oxygen measuring device for measuring dissolved oxygen of the treatment liquid stored in the storage space.

19. The apparatus of claim 18, further comprising:
a controller,
wherein the controller controls the first opening/closing valve and the decompressor to decompress the storage space by opening the first opening/closing valve while the used treatment liquid is recovered through the recovery pipe.

20. The apparatus of claim 18, wherein the liquid treating chamber is provided in plural, and
the recovery pipe includes:
a plurality of discharge pipes connected to the plurality of liquid treating chambers, respectively; and
collective pipes to which the plurality of discharge pipes is connected and the recovery tank is connected.
